(19) United States
(12) Patent Application Publication
(10) Pub. No.: US 2025/0089569 A1
(43) Pub. Date: Mar. 13, 2025

(54) Thermocouple Power Generation Unit, Module, and Device

(71) Applicants: Pin Sheng Chen, New Taipei City (TW); Man Huang Chen, New Taipei City (TW)

(72) Inventors: Pin Sheng Chen, New Taipei City (TW); Man Huang Chen, New Taipei City (TW)

(21) Appl. No.: 18/826,199

(22) Filed: Sep. 6, 2024

(30) Foreign Application Priority Data
Sep. 13, 2023 (TW) 112134911

(51) Int. Cl. H10N 10/817; H10N 10/01; H10N 10/17

(52) U.S. Cl. CPC H10N 10/817; H10N 10/01; H10N 10/17

(57) ABSTRACT

A thermocouple power generation unit, module, and device that generate electricity using a temperature difference, characterized by compact size and high efficiency. The thermocouple power generation unit comprises an insulating substrate, a cathode alloy section, a first insulating layer, an anode alloy section, a second insulating layer, a cathode conductive lead, and an anode conductive lead. The cathode and anode alloy portions respectively include multiple cathode and anode nanowires that are etched from cathode and anode alloy materials and arranged at equal intervals. A single pair of cathode and anode nanowires forms multiple power generation units, which are arranged in series, with their free ends respectively connected to the corresponding cathode and anode conductive leads. The connection points between the cathode and anode nanowires of the power generation units form multiple power generation points.

### FIELD OF THE INVENTION

The present invention belongs to the field of thermal power generation and relates to a thermocouple power generation unit, module, and device that are compact in size yet highly efficient.

### BACKGROUND OF THE INVENTION

Due to the development of modern industry and human economic activities, energy consumption continues to rise. The main methods of energy use are heating, transportation, and electricity. The growth rate of electricity consumption is inevitably exceeding the overall increase in energy consumption, leading to the rapid depletion of the Earth's finite fossil fuel resources. At the same time, the emission of large amounts of carbon dioxide is causing environmental concerns. Currently, non-renewable energy sources remain the primary module of the energy structure, with fossil fuels dominating the supply of energy. Therefore, how to efficiently utilize energy has become a critically important issue.

One approach is the use of a solid-state thermoelectric generator that leverages the thermocouple effect between conductors made of different metals or alloys to generate electricity from temperature differences. The inventors of the present application previously proposed a patent (see Patent Document 1) for a solid-state thermoelectric generator and device that generates electricity through the thermocouple effect between different metals or alloys. Compared to traditional semiconductor thermoelectric devices, it offers higher power generation efficiency, lower manufacturing costs, longer service life, and the ability to generate power at lower temperatures, with the added benefit of recyclability.

However, to maximize power generation efficiency, the solid-state thermoelectric generator described in Patent Document 1 requires an increased number of thermoelectric generation points. When the number of generation points exceeds a certain threshold, the overall size of the device becomes excessively large, negatively affecting its industrial applicability and thus reducing the willingness to use it.

In light of the above, how to provide a thermocouple power generation unit, module, and device that can solve the aforementioned problems has become the subject of improvement for the present invention.

The aforementioned is disclosed in the prior art document, Taiwan Invention Patent Publication No. I 334005, Solid-State Thermoelectric Generator and Device.

### SUMMARY OF THE INVENTION

The objective of the present invention is to provide a thermocouple power generation unit, module, and device that are compact in size yet highly efficient.

To solve the above problems and achieve the objective of the present invention, three technical solutions are provided:

The first technical solution is implemented as follows: A thermocouple power generation unit comprises an insulating substrate; a cathode alloy portion, positioned on the insulating substrate, containing multiple cathode nanowires made of cathode alloy material etched and arranged at equal intervals; a first insulating layer, positioned on the cathode alloy portion, containing contact points corresponding to each end of the cathode nanowires formed by etching; an anode alloy portion, positioned on the first insulating layer, containing multiple anode nanowires made of anode alloy material etched and arranged at equal intervals, with at least one end of each anode nanowire electrically connected to an adjacent cathode nanowire through the contact points, forming several power generation units arranged in series; a second insulating layer, positioned on the anode alloy portion; a cathode conductive lead electrically connected to the contact point at the end of the cathode nanowire of the power generation unit not connected to the adjacent power generation unit; and an anode conductive lead electrically connected to the contact point at the end of the anode nanowire of the power generation unit not connected to the adjacent power generation unit. The connection between the anode and cathode nanowires of each power generation unit forms multiple power generation points.

Furthermore, the cathode alloy material of the cathode alloy portion is a nickel-copper alloy; the anode alloy material of the anode alloy portion is a nickel-chromium alloy.

Additionally, the thermocouple power generation unit is electrically connected to a rectifying diode through the anode conductive lead.

The rectifying diode may be positioned either inside or outside the thermocouple power generation unit.

The second technical solution is implemented as follows: A thermocouple power generation module comprises multiple layers stacked and electrically connected in series, as described in the thermocouple power generation unit above; a cathode wire electrically connected to the cathode conductive lead of the frontmost thermocouple power generation unit; and an anode wire electrically connected to the anode conductive lead of the rearmost thermocouple power generation unit.

Furthermore, the thermocouple power generation module is electrically connected to a rectifying diode through the anode conductive lead or the anode wire.

The rectifying diode may be positioned either inside or outside the thermocouple power generation module.

The third technical solution is implemented as follows: A thermocouple power generation device is characterized by having multiple thermocouple power generation modules electrically connected in parallel as described above; a cathode wire positioned outside the thermocouple power generation device and electrically connected to the cathode conductive leads of each thermocouple power generation module; an anode wire positioned outside the thermocouple power generation device and electrically connected to the anode conductive leads of each thermocouple power generation module; and an insulator covering each thermocouple power generation module.

Furthermore, the thermocouple power generation device is electrically connected to a rectifying diode through the anode conductive lead or the anode wire.

The rectifying diode may be positioned either inside or outside the insulator.

The present invention has the following advantageous effects:

The thermocouple power generation unit, module, and device of the present invention, due to the application of nanoscale chip manufacturing processes, allow for a large number of power generation points within a unit area. Even though the basic power generation unit produces microvolts, through series and parallel connections, volt-level electricity can be generated, significantly improving power generation efficiency. Most importantly, the device is compact, easy to produce and install, and does not suffer from weak power generation, making it beneficial for widespread application.

The invention uses commonly available base metals as power generation materials instead of precious metals, resulting in lower manufacturing costs and simpler manufacturing processes.

By utilizing the insulating substrate, cathode alloy portion, first insulating layer, anode alloy portion, second insulating layer, cathode conductive lead, and anode conductive lead, the thermocouple power generation unit of the present invention is constructed differently from traditional thermoelectric modules, offering a broader operating temperature range.

The overall service life of the invention is long, with no moving parts, resulting in low failure rates and no secondary pollution. In case of failure or damage, the modules can be recycled and remanufactured, minimizing resource consumption.

### BRIEF DESCRIPTION OF THE DRAWINGS

FIG. 1 is a perspective view of the thermocouple power generation unit of the present invention;

FIG. 2 is an exploded perspective view of the thermocouple power generation unit of the present invention;

FIG. 3 is a flow chart showing the manufacturing process of the thermocouple power generation unit of the present invention;

FIG. 4 is a perspective view of another thermocouple power generation unit of the present invention;

FIG. 5 is a perspective view of the thermocouple power generation module of the present invention;

FIG. 6 is an exploded perspective view of the thermocouple power generation module of the present invention;

FIG. 7 is a perspective view of another thermocouple power generation module of the present invention;

FIG. 8 is a perspective view of the thermocouple power generation device of the present invention;

FIG. 9 is an exploded perspective view of the thermocouple power generation device of the present invention;

FIG. 10 is a perspective view of another thermocouple power generation device of the present invention.

### DETAILED DESCRIPTION OF THE EMBODIMENTS

The technical solutions of the present invention will now be described in detail through embodiments with reference to the drawings. The embodiments described in the present invention are merely some examples and not all embodiments. Other embodiments obtained by those skilled in the art without making inventive efforts should also be within the scope of the present invention.

To facilitate understanding and maintain simplicity in the drawings, the FIGS. from 1 to 10 have been magnified, though the actual thermocouple power generation unit 100, thermocouple power generation module 200, and thermocouple power generation device 300 in the present invention are manufactured using nanoscale chip processing.

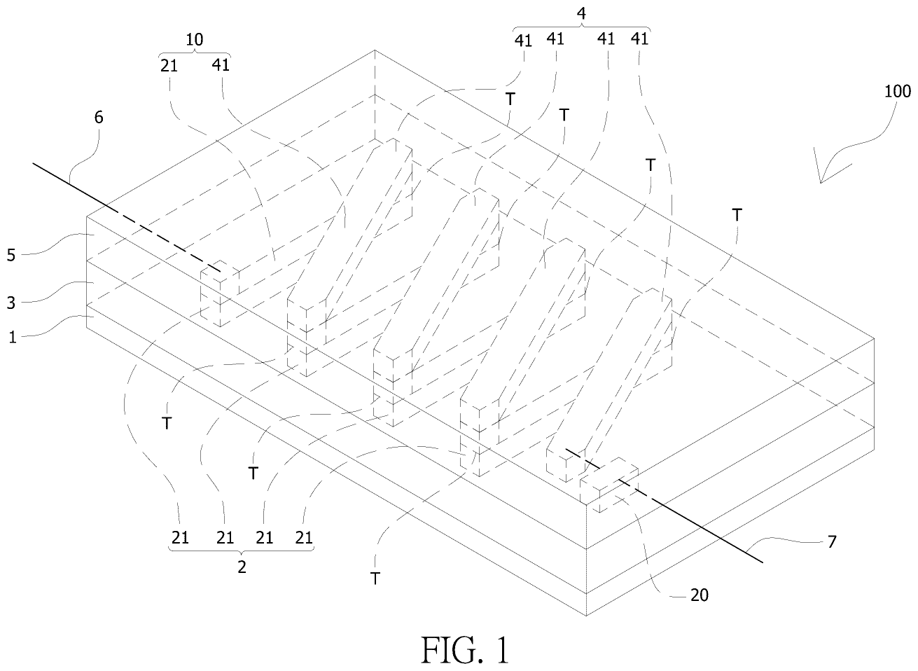

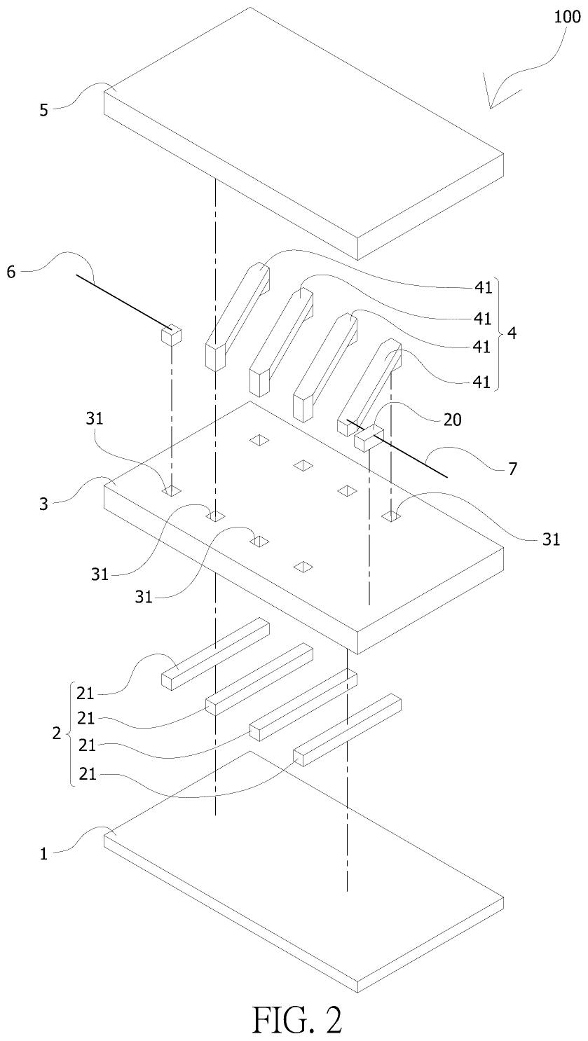

As shown in FIGS. 1 to 4, a thermocouple power generation unit comprises an insulating substrate 1; a cathode alloy portion 2 positioned on the insulating substrate 1, containing multiple cathode nanowires 21 made of cathode alloy material etched and arranged at equal intervals; a first insulating layer 3 positioned on the cathode alloy portion 2, containing contact points 31 corresponding to each end of the cathode nanowires 21 formed by etching; an anode alloy portion 4 positioned on the first insulating layer 3, containing multiple anode nanowires 41 made of anode alloy material etched and arranged at equal intervals. At least one end of each anode nanowire 41 is electrically connected to an adjacent cathode nanowire 21 through the contact points 31, forming several power generation units 10 arranged in series; a second insulating layer 5 positioned on the anode alloy portion 4; a cathode conductive lead 6 electrically connected to the contact point 31 at the end of the cathode nanowire 21 of the power generation unit 10 not connected to the adjacent power generation unit 10; and an anode conductive lead 7 electrically connected to the contact point 31 at the end of the anode nanowire 41 of the power generation unit 10 not connected to the adjacent power generation unit 10. The connection between the anode and cathode nanowires 41 and 21 of each power generation unit 10 forms multiple power generation points T.

Through the coordination of the insulating substrate 1, cathode alloy portion 2, first insulating layer 3, anode alloy portion 4, second insulating layer 5, cathode conductive lead 6, and anode conductive lead 7, the thermocouple power generation unit 100 of the present invention is constructed. Using nanoscale chip manufacturing, more power generation units 10 formed by the cathode nanowires 21 and anode nanowires 41 can be installed within a single area. With more power generation points T from the series-connected power generation units 10, more electricity can be generated. The output electricity is in microvolts per degree Celsius. For example, with a 7-nanometer process, approximately 96.27 million transistors per square millimeter can be replaced with an equivalent number of power generation units 10, resulting in approximately 192.53 volts of electricity generated per degree Celsius temperature difference in ideal conditions. The thermocouple power generation unit 100 is compact, highly efficient, easy to install, and environmentally friendly.

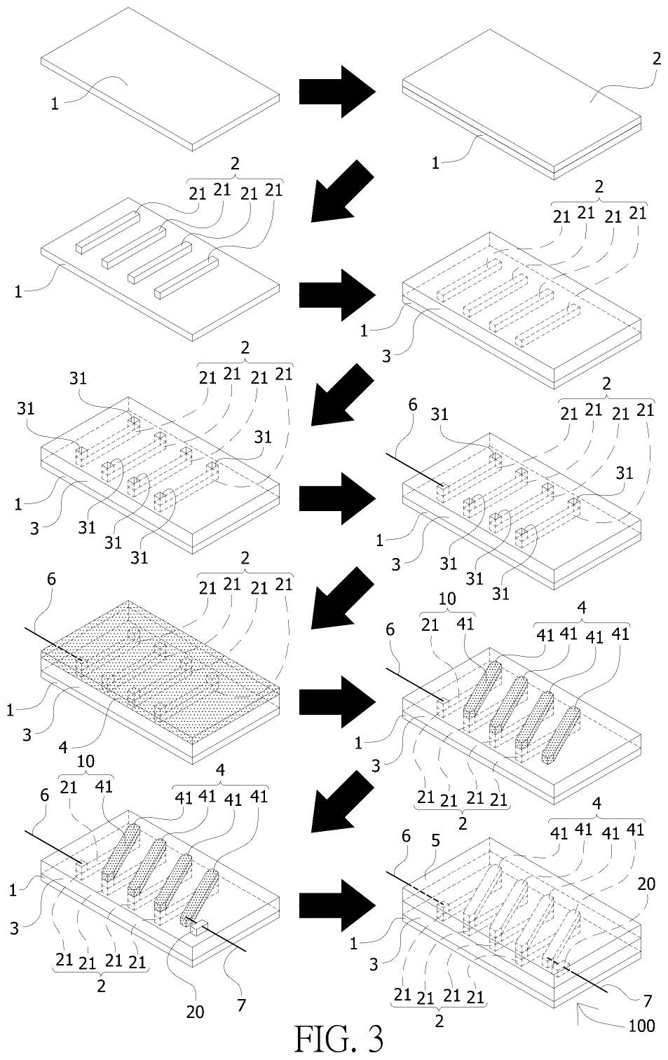

As shown in FIG. 3, the basic manufacturing process of the thermocouple power generation unit 100 of the present invention is illustrated. An insulating substrate 1 is prepared, and a layer of cathode alloy material is deposited on it, followed by etching to form multiple cathode nanowires 21 arranged at equal intervals. A first insulating layer 3 is then deposited and etched to form contact points 31 corresponding to each end of the cathode nanowires 21. The anode conductive lead 7 is connected to the contact point 31 at the end of the outermost cathode nanowire 21, and a rectifying diode 20 is electrically connected. Finally, a second insulating layer 5 is deposited to complete the thermocouple power generation unit 100.

The cathode alloy material of the cathode alloy portion 2 is nickel-copper (NiCu) alloy, while the anode alloy material of the anode alloy portion 4 is nickel-chromium (NiCr) alloy.

The cathode and anode alloy portions use commonly available industrial metal alloys, not precious metals, making the manufacturing cost lower and facilitating mass production and use.

By using a combination of nickel-copper (NiCu) alloy and nickel-chromium (NiCr) alloy, an E-type thermocouple is formed, with a higher thermoelectric potential output of about 68 microvolts per degree Celsius (μV/° C.). The applicable temperature range is −200° C. to 900° C., meeting the needs of most applications with fewer usage restrictions, promoting wider application.

As shown in FIGS. 1 to 4, the thermocouple power generation unit 100 is also electrically connected to a rectifying diode 20 through the anode conductive lead 7.

The application of the rectifying diode 20 ensures that the current generated by the thermocouple power generation unit 100 flows in a single direction, facilitating output applications.

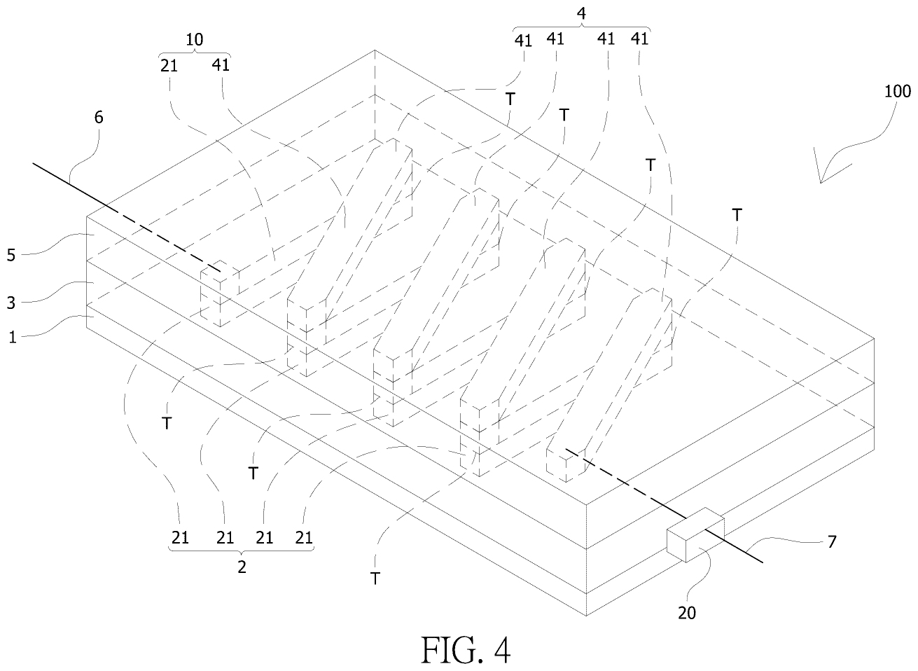

As shown in FIGS. 1 and 4, the rectifying diode 20 can be positioned inside or outside the thermocouple power generation unit 100.

In one embodiment, as shown in FIG. 1, the rectifying diode 20 is placed inside the thermocouple power generation unit 100 for direct application. In another embodiment, as shown in FIG. 4, the rectifying diode 20 is placed outside the thermocouple power generation unit 100 to increase the range of applications, allowing adjustments to meet different usage needs of the thermocouple power generation unit 100. The different placement of the rectifying diode 20 improves applicability.

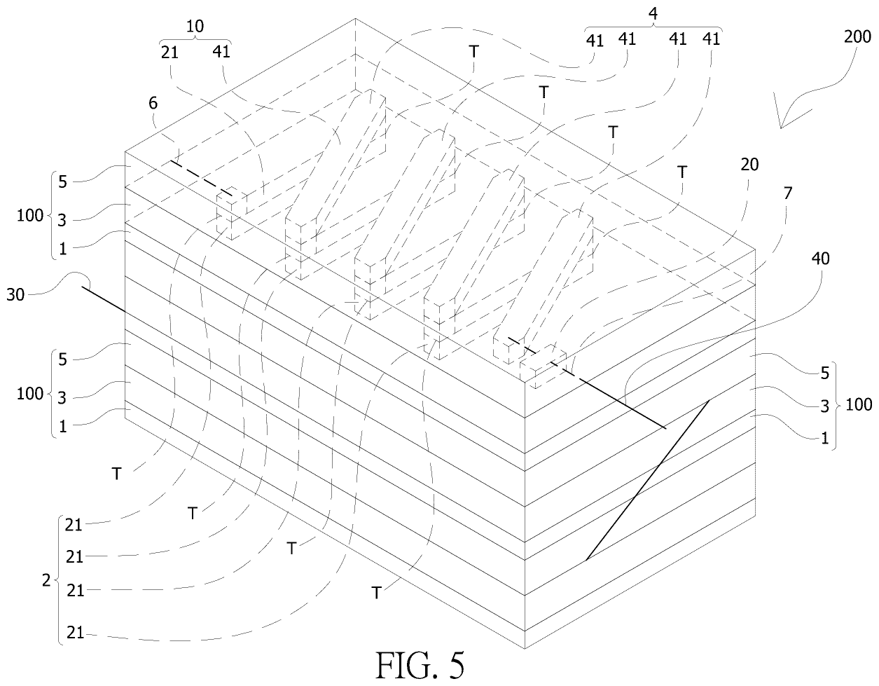

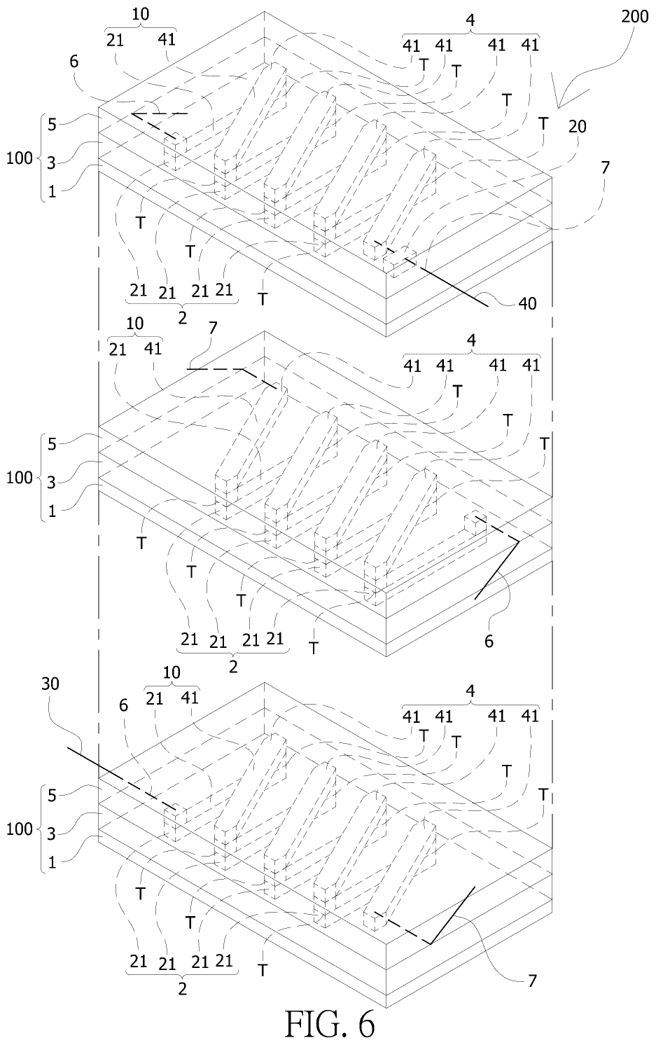

As shown in FIGS. 5 to 7, a thermocouple power generation module is disclosed, comprising multiple layers stacked and electrically connected in series as described in the thermocouple power generation unit 100; a cathode wire 30 electrically connected to the cathode conductive lead 6 of the frontmost thermocouple power generation unit 100; and an anode wire 40 electrically connected to the anode conductive lead 7 of the rearmost thermocouple power generation unit 100.

The thermocouple power generation module 200 of the present invention stacks the thermocouple power generation units 100 three-dimensionally and electrically connects them in series, allowing for more power generation units 10 to be installed within a single area. The three-dimensional structure increases unit density, providing more power generation points T and improving power generation efficiency, which is beneficial for industrial applications.

As shown in FIGS. 5 to 7, the thermocouple power generation module 200 is also electrically connected to a rectifying diode 20 through the anode conductive lead 7 or the anode wire 40.

The application of the rectifying diode 20 ensures that the current generated by the thermocouple power generation module 200 flows in a single direction, facilitating output applications.

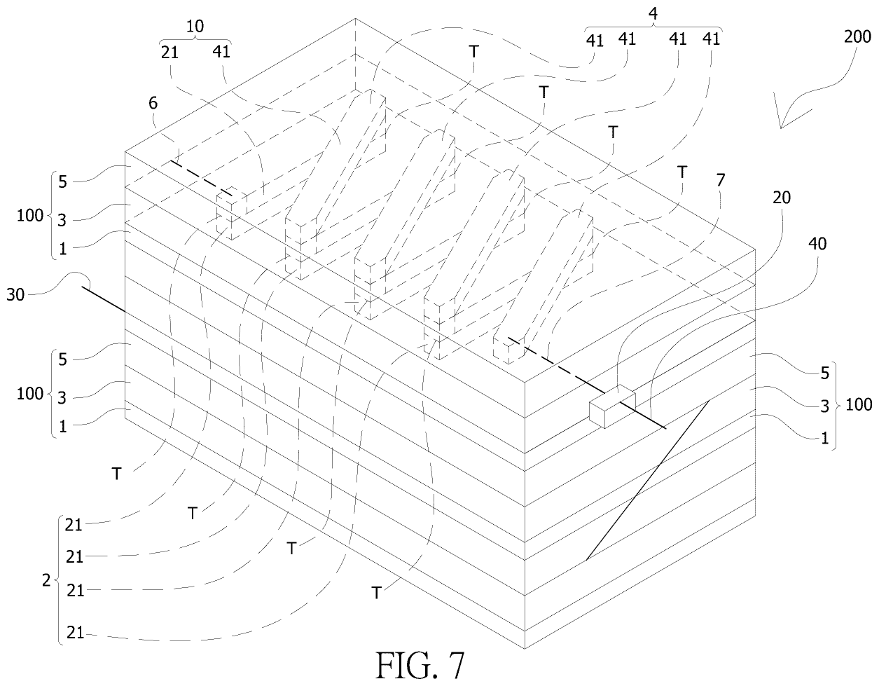

As shown in FIGS. 5 and 7, the rectifying diode 20 can be positioned inside or outside the thermocouple power generation module 200.

In one embodiment, as shown in FIG. 5, the rectifying diode 20 is placed inside the thermocouple power generation module 200 for direct application. In another embodiment, as shown in FIG. 7, the rectifying diode 20 is placed outside the thermocouple power generation module 200 to increase the range of applications, allowing adjustments to meet different usage needs of the thermocouple power generation module 200. The different placement of the rectifying diode 20 improves applicability.

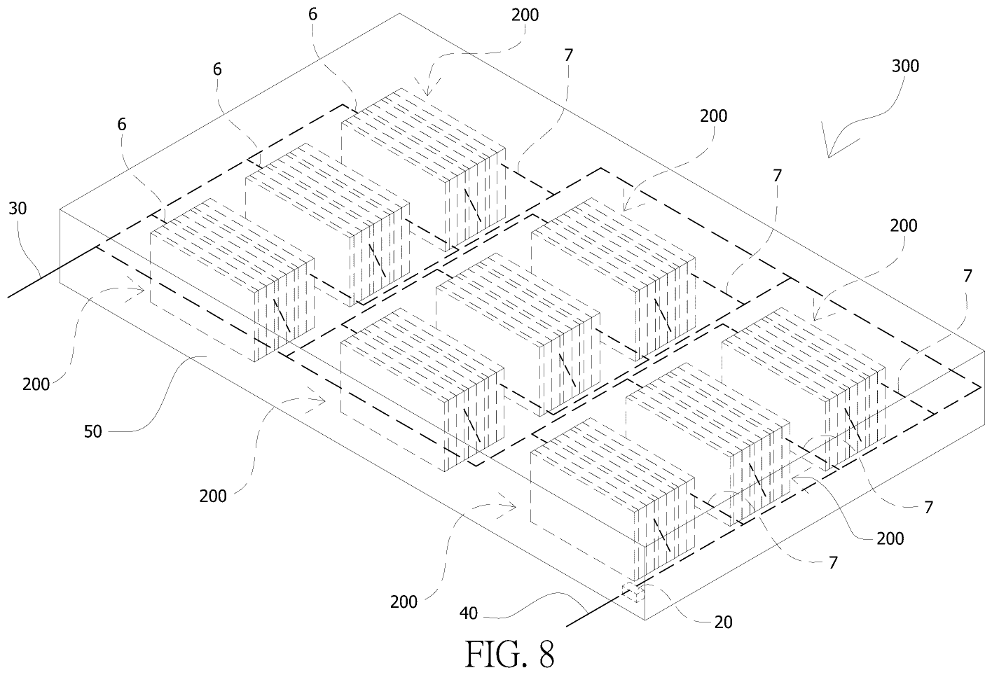

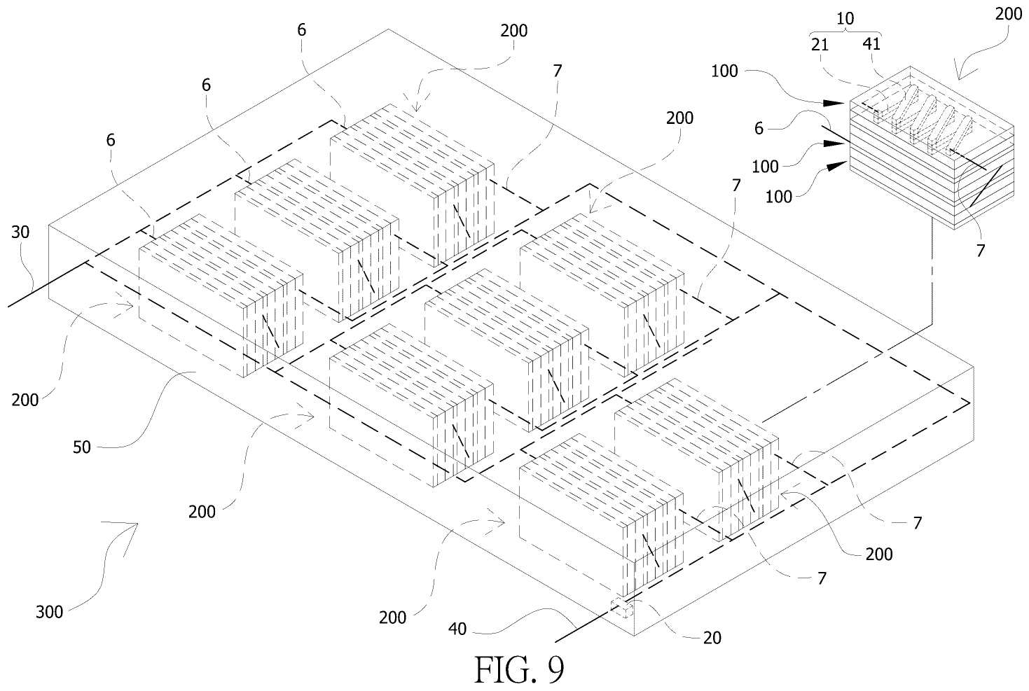

As shown in FIGS. 8 to 10, a thermocouple power generation device is disclosed, comprising multiple thermocouple power generation modules 200 electrically connected in parallel as described in the thermocouple power generation unit 100; a cathode wire 30 positioned outside the thermocouple power generation device 300 and electrically connected to the cathode conductive leads 6 of each thermocouple power generation module 200; an anode wire 40 positioned outside the thermocouple power generation device 300 and electrically connected to the anode conductive leads 7 of each thermocouple power generation module 200; and an insulator 50 covering each thermocouple power generation module 200.

The thermocouple power generation device 300 connects multiple thermocouple power generation modules 200 in parallel, using an insulator 50 to cover each thermocouple power generation module 200, making the device easy to apply. The thermocouple power generation device 300, like a chip, has a broader operating temperature range, is more practical, can be used in various places with waste heat, converts waste heat into electrical energy, improves energy utilization efficiency, and can be applied to geothermal, seawater temperature difference power generation, and other areas. The device is not prone to failure, reduces costs, and promotes wider application.

Additionally, the insulator 50 can be one of metal oxide, ceramic, or polymer (plastic) to increase industrial applicability.

As shown in FIGS. 8 to 10, the thermocouple power generation device 300 is also electrically connected to a rectifying diode 20 through the anode conductive lead 7 or the anode wire 40.

The application of the rectifying diode 20 ensures that the current generated by the thermocouple power generation device 300 flows in a single direction, facilitating output applications.

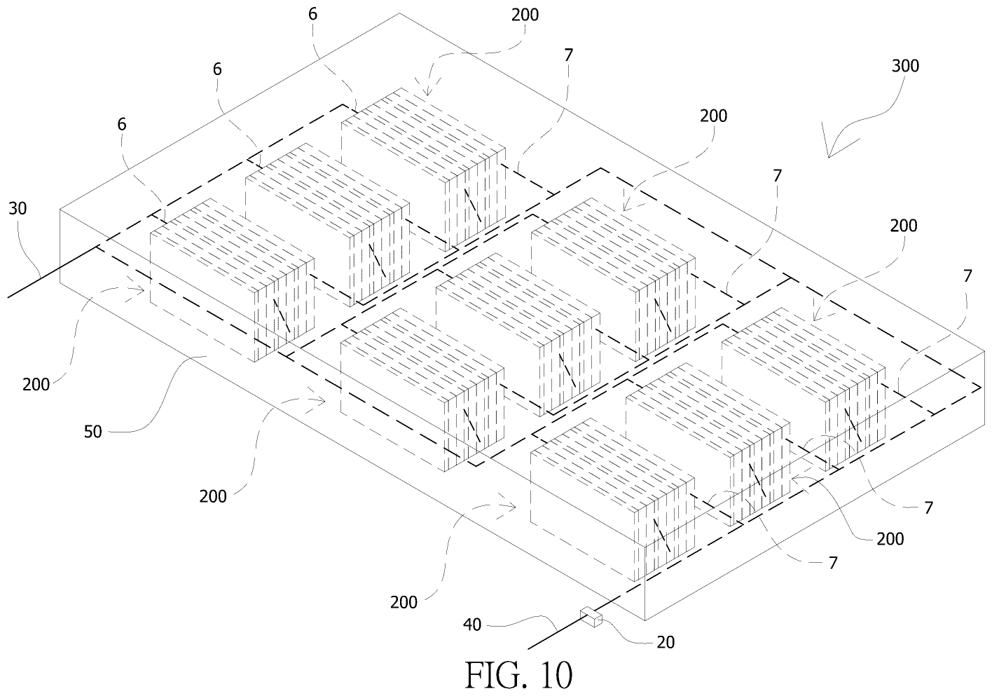

As shown in FIGS. 8 and 10, the rectifying diode 20 can be positioned inside or outside the insulator 50.

In one embodiment, as shown in FIG. 8, the rectifying diode 20 is placed inside the insulator 50 for direct application. In another embodiment, as shown in FIG. 10, the rectifying diode 20 is placed outside the insulator 50 to increase the range of applications, allowing adjustments to meet different usage needs. The different placement of the rectifying diode 20 improves industrial applicability.

The above-described embodiments based on the FIGS. explain in detail the structure, features, and functional effects of the present invention; however, the above description is merely a preferred embodiment of the present invention. The invention is not limited to the embodiments shown in the drawings, and any modifications that are consistent with the spirit of the invention should fall within the scope of the patent protection of the present invention.

We claim:

1. A thermocouple power generation unit, comprising:
an insulating substrate (1);
a cathode alloy portion (2) disposed on the insulating substrate (1), the cathode alloy portion (2) comprising a plurality of cathode nanowires (21) etched from cathode alloy material and arranged at equal intervals;
a first insulating layer (3) disposed on the cathode alloy portion (2), the first insulating layer (3) having contact points (31) corresponding to the ends of each cathode nanowire (21), the contact points (31) being formed by etching;
an anode alloy portion (4) disposed on the first insulating layer (3), the anode alloy portion (4) comprising a plurality of anode nanowires (41) etched from anode alloy material and arranged at equal intervals, wherein at least one end of each anode nanowire (41) is electrically connected to a cathode nanowire (21) through the contact points (31), forming a plurality of serially arranged power generation units (10);
a second insulating layer (5) disposed on the anode alloy portion (4);
a cathode conductive lead (6) electrically connected to the contact point (31) at the end of the cathode nanowire (21) in the power generation unit (10) that is not connected to another power generation unit (10);
an anode conductive lead (7) electrically connected to the contact point (31) at the end of the anode nanowire (41) in the power generation unit (10) that is not connected to another power generation unit (10);
wherein the electrical connections between the anode nanowires (41) and the cathode nanowires (21) in the power generation units (10) form a plurality of power generation points (T).

2. The thermocouple power generation unit according to claim 1, wherein the cathode alloy portion (2) is made of nickel-copper (NiCu) alloy, and the anode alloy portion (4) is made of nickel-chromium (NiCr) alloy.

3. The thermocouple power generation unit according to claim 2, wherein the thermocouple power generation unit (100) is electrically connected to a rectifying diode (20) through the anode conductive lead (7).

4. The thermocouple power generation unit according to claim 3, wherein the rectifying diode (20) is disposed inside or outside the thermocouple power generation unit (100).

5. A thermocouple power generation module, comprising:
a plurality of stacks of thermocouple power generation units (100) as described in claim 1, wherein each of the plurality of thermocouple power generation units (100) is electrically connected in series;
a cathode lead (30) electrically connected to the cathode conductive lead (6) of the foremost thermocouple power generation unit (100);
an anode lead (40) electrically connected to the anode conductive lead (7) of the rearmost thermocouple power generation unit (100).

6. The thermocouple power generation module according to claim 5, wherein the thermocouple power generation module (200) is electrically connected to a rectifying diode (20) through the anode conductive lead (7) or the anode lead (40).

7. The thermocouple power generation module according to claim 6, wherein the rectifying diode (20) is disposed inside or outside the thermocouple power generation module (200).

8. A thermocouple power generation device, comprising:
a plurality of thermocouple power generation modules (200) as described in claim 5, wherein each of the plurality of thermocouple power generation modules (200) is electrically connected in parallel;
a cathode lead (30) disposed outside the thermocouple power generation device (300) and electrically connected to the cathode conductive leads (6) of each thermocouple power generation module (200);
an anode lead (40) disposed outside the thermocouple power generation device (300) and electrically connected to the anode conductive leads (7) of each thermocouple power generation module (200);
an insulator (50) that covers each of the thermocouple power generation modules (200).

9. The thermocouple power generation device according to claim 8, wherein the thermocouple power generation device (300) is electrically connected to a rectifying diode (20) through the anode conductive lead (7) or the anode lead (40).

10. The thermocouple power generation device according to claim 9, wherein the rectifying diode (20) is disposed inside or outside the insulator (50).
